(19) United States
(12) Patent Application Publication
(10) Pub. No.: US 2024/0176053 A1
(43) Pub. Date: May 30, 2024

(54) Pixel Scale Guided Mode Resonant Filter For Hyperspectral Sensing

(71) Applicant: SONY SEMICONDUCTOR SOLUTIONS CORPORATION, Kanagawa (JP)

(72) Inventors: Trevor O'Loughlin, Rochester, NY (US); Gui Gui, Victor, NY (US); Frederick T Brady, Rochester, NY (US); Sungin Han, Rochester, NY (US); Victor A. Lenchenkov, Rochester, NY (US)

(73) Assignee: SONY SEMICONDUCTOR SOLUTIONS CORPORATION, Kanagawa (JP)

(21) Appl. No.: 18/060,275

(22) Filed: Nov. 30, 2022

(51) Int. Cl. G02B 5/20; G02B 1/00; H01L 27/146

(52) U.S. Cl. CPC G02B 5/203; G02B 1/002; H01L 27/14625

(57) ABSTRACT

Sensors and systems are provided. A sensor as disclosed includes a plurality of pixels disposed within an array. Each pixel is associated with a hyperspectral filter including a metamaterial and a metal grating capable of passing light of a particular wavelength range through to an image sensor. Systems include the use of an aluminum grating separated from a metamaterial including TiO₂ and Si₃N₄ by a SiO₂ coupling layer as a filter mounted on a substrate.

### FIELD

The present disclosure relates generally to filters and more particularly to a hyperspectral imaging filter.

### BACKGROUND

Digital image sensors are commonly used in a variety of electronic devices, such as handheld cameras, security systems, telephones, computers, and tablets, to capture images. In a typical arrangement, light sensitive areas or pixels are arranged in a two-dimensional array having multiple rows and columns of pixels. Each pixel generates an electrical charge in response to receiving photons as a result of being exposed to incident light. For example, each pixel can include a photodiode that generates charge in an amount that is generally proportional to the amount of light (i.e., the number of photons) incident on the pixel during an exposure period. The charge can then be read out from each of the pixels, for example through peripheral circuitry.

In conventional color image sensors, absorptive color filters are used to enable the image sensor to detect the color of incident light. The color filters are typically disposed in sets (e.g., of red, green, and blue (RGB); cyan, magenta, and yellow (CMY); or red, green, blue, and infrared (RGBIR)). Such arrangements have about 3-4 times lower sensitivity and signal to noise ratio (SNR) at low light conditions, color crosstalk, color shading at high chief ray angles (CRA), and lower spatial resolution due to color filter patterning resulting in lower spatial frequency as compared to monochrome sensors without color filters. However, the image information provided by a monochrome sensor does not include information about the color of the imaged object.

In addition, conventional color and monochrome image sensors incorporate non-complementary metal-oxide semiconductor (CMOS), polymer-based materials, for example to form filters and micro lenses for each of the pixels, which result in image sensor fabrication processes that are more time-consuming and expensive than processes that only require CMOS materials. Moreover, the resulting devices suffer from compromised reliability and operational life, as the included color filters and micro lenses are subject to weathering and performance that degrades at a much faster rate than inorganic CMOS materials. In addition, the processing required to interpolate between pixels of distinct colors in order to produce a continuous image is significant.

Hyperspectral imaging has increased in popularity recently for its ability to separate different wavelengths of light in not only the visible, but the near infrared (NIR). Currently, it shows a large amount of potential for use with agriculture, sensing water content of crops for example. However, most hyperspectral imagers are large systems, where the filter is separate from the image sensor (IS). Combining a filter and IS together results in a snapshot hyperspectral imager that can be smaller. However, the integration of conventional snapshot filters with current ISs requires specialized equipment and procedures, making it not ideal from a processing standpoint.

### SUMMARY

As described herein, a hyperspectral imaging filter may be designed to permit light of a particular wavelength or range of wavelengths. Using embodiments as described herein, the overall thickness of a filter may be constant while the wavelengths of light passed by the filter may be adjusted. For example, two filters may each be of a same thickness while being configured to pass light of a completely different range of wavelengths.

A filter as described herein may comprise a metal grating layer and a metamaterial layer. Each of the metal grating and metamaterial layers may be designed in tandem to effectively select a wavelength or range of wavelengths of light which should be permitted to pass through the filter and reach an image sensor.

For each filter, both a design of the grating and a material of the grating may be chosen to select a particular refractive index. A design of a grating may be adjusted between a grating sized to resonate with shorter wavelengths of light and a grating sized to resonate with longer wavelengths of light. By changing the design of the grating as described herein, the spectral system can effectively be divided and by changing the refractive index of the grating, the divided spectral system can be tuned to select a particular wavelength or range of wavelengths.

The metamaterial, which may also be referred to as a resonant region, of the filter can also be adjusted to select a particular wavelength or range of wavelengths. By adjusting both the grating and the resonant region together, a larger range of wavelengths of potential wavelengths can be allowed through the filter.

The present disclosure relates to hyperspectral filters. It specifically relates to the design of a material stack that is being considered for a hyperspectral test chip. The design consists of a single, thin (e.g., less than 30 nm) metal grating that is coupled to a resonant cavity mode of a high refractive index waveguide. The two-dimensional nature of the grating makes the grating polarization independent. The stack layout ensures minimal processing for operation over a wide spectral range, from blue to near infrared (e.g., 400 nm-1000 nm).

As described herein, a mode resonant filter for hyperspectral sensing may comprise a metal grating, a coupling layer, and a metamaterial. In some embodiments, the metal grating comprises an aluminum (Al) grating. An Al grating may be, for example, less than 30 nm thick.

An Al grating as described herein may comprise a grid of Al grating squares surrounded by SiO₂. Al grating squares may be, for example, between 200 nm and 250 nm wide. Each Al grating square may be separated by, for example, between 100 nm and 150 nm. In some embodiments, an Al grating may comprise parallel lines of Al separated by parallel lines of SiO₂, or concentric circles of Al separated by circles of SiO₂.

In some embodiments, the metamaterial of a filter comprises one or more of Si₃N₄ and TiO₂. The metamaterial may comprise, for example, a plurality of cylindrical columns of TiO₂ surrounded by Si₃N₄. Cylindrical columns of TiO₂ are, at least in some embodiments, between 250 nm and 300 nm in diameter and between 150 nm and 250 nm in depth. Each cylindrical column of TiO₂ may be separated from another cylindrical column of TiO₂ by between 100 nm and 150 nm. In some embodiments, the metamaterial is surrounded by an isolation region which may comprise one or more of an Al, a dielectric, and air.

By designing filters comprising a metamaterial layer and a grating as described herein to have a particular refractive indices, an array of filters may be deployed on a sensor such that each pixel may receive light of a particular wavelength or range of wavelengths. Such filters may each be of a common thickness such that the filters are easy to install and may be fitted with micro lenses and/or color filters as needed.

Additional features and advantages of embodiments of the present disclosure will become more readily apparent from the following description, particularly when considered together with the accompanying drawings.

### BRIEF DESCRIPTION OF THE DRAWINGS

FIG. 1 depicts elements of a color sensing image sensor in accordance with embodiments of the present disclosure;

FIG. 2 is a plan view of a portion of an exemplary color sensing image sensor;

FIG. 3A is an illustration of a stack layout of a substrate with a spectral filter in accordance with one or more of the embodiments described herein;

FIG. 3B is an illustration of a grating in accordance with one or more of the embodiments described herein;

FIG. 3C is an illustration of a metamaterial in accordance with one or more of the embodiments described herein;

FIGS. 4A and 4B each illustrate a stack layout of a substrate with a spectral filter in accordance with one or more of the embodiments described herein;

FIGS. 5A-5F each illustrate a grating in accordance with one or more of the embodiments described herein;

FIGS. 6A-6F each illustrate a metamaterial in accordance with one or more of the embodiments described herein; and

FIG. 7 illustrates a grid of gratings in accordance with one or more of the embodiments described herein.

### DETAILED DESCRIPTION

As described herein, a hyperspectral filter of a constant thickness may be capable of covering a plurality of pixels and enabling each pixel to receive light filtered through a different refractive index based on the materials and design of the filter. This enables a single sensor, such as an IS, with any number of pixels to have a level light-receiving surface and each pixel can receive light at a different wavelength. By having a constant overall thickness, the filter may be easier to manufacture, and light filters and micro lenses may be easier to apply to an image sensor.

A filter as described herein can be used to select one wavelength range from a larger range of light to reach one or more pixels. Such a filter may be sized to cover one or more pixels. Filters may be placed directly next to other filters such as to create a grid or array of filters for use with a single sensor.

Many conventional filters are polarized which causes performance issues depending on the polarization of received light. Using a filter as described herein, a sensor may have a similar response to light no matter how the light is polarized. Using a square grid of grating as described in certain embodiments herein resolves polarization issues and enables an image sensor to perform substantially the same regardless of the polarization of received light.

As described herein, a filter may be insensitive to polarization and may enable a large spectral response range. Also, through the use of isolation materials, pixel isolation can be incorporated into the design of a filter. Furthermore, because each filter can be the same thickness regardless of the wavelengths of light which pass, separate pixels can be used for individual pixels and a flat top covering of multiple filters enables the use of an array of color filters and micro lenses.

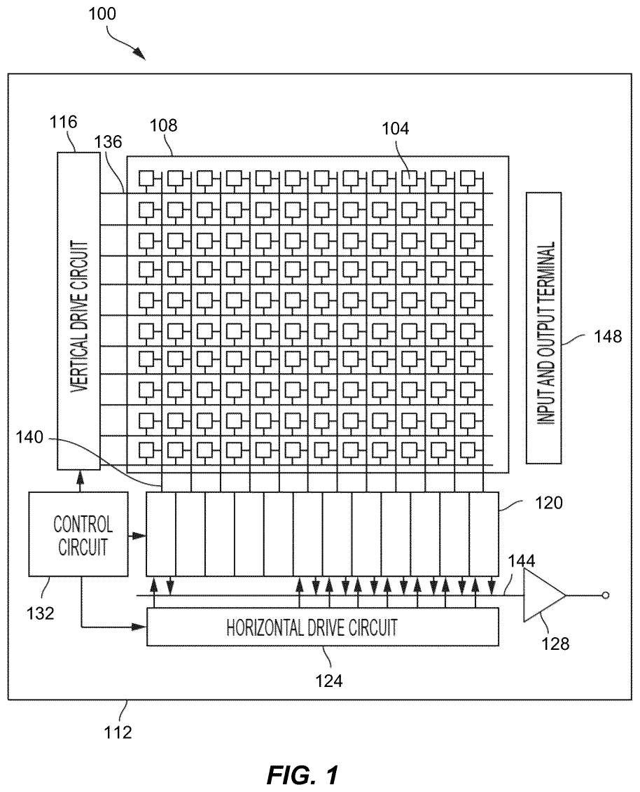

As illustrated in FIG. 1, an image sensor or device 100 in accordance with embodiments of the present disclosure may include a plurality of pixels 104 disposed in an array 108. More particularly, the pixels 104 can be disposed within an array 108 having a plurality of rows and columns of pixels 104. Moreover, pixels 104 may be formed in an imaging or semiconductor substrate 112. In addition, one or more peripheral or other circuits can be formed in connection with the imaging substrate 112. Examples of such circuits include a vertical drive circuit 116, a column signal processing circuit 120, a horizontal drive circuit 124, an output circuit 128, and a control circuit 132. As described in greater detail elsewhere herein, each of the pixels 104 within a color sensing image sensor 100 in accordance with embodiments of the present disclosure includes a plurality of photosensitive sites or sub-pixels. A spectral filter as described herein may be installed between the pixels 104 and one or more micro lenses or color filters.

The control circuit 132 can receive data for instructing an input clock, an operation mode, and the like, and can output data such as internal information related to the image sensor 100. Accordingly, the control circuit 132 can generate a clock signal that provides a standard for operation of the vertical drive circuit 116, the column signal processing circuit 120, and the horizontal drive circuit 124, and control signals based on a vertical synchronization signal, a horizontal synchronization signal, and a master clock. The control circuit 132 outputs the generated clock signal in the control signals to the various other circuits and components.

The vertical drive circuit 116 can, for example, be configured with a shift register, can operate to select a pixel drive wiring 136, and can supply pulses for driving sub-pixels of a pixel 104 through the selected drive wiring 136 in units of a row. The vertical drive circuit 116 can also selectively and sequentially scan elements of the array 108 in units of a row in a vertical direction, and supply the signals generated within the pixels 104 according to an amount of light they have received to the column signal processing circuit 120 through a vertical signal line 140.

The column signal processing circuit 120 can operate to perform signal processing, such as noise removal, on the signal output from the pixels 104. For example, the column signal processing circuit 120 can perform signal processing such as a correlated double sampling (CDS) for removing a specific fixed patterned noise of a selected pixel 104 and an analog to digital (A/D) conversion of the signal.

The horizontal drive circuit 124 can include a shift register. The horizontal drive circuit 124 can select each column signal processing circuit 120 in order by sequentially outputting horizontal scanning pulses, causing each column signal processing circuit 122 to output a pixel signal to a horizontal signal line 144.

The output circuit 128 can perform predetermined signal processing with respect to the signals sequentially supplied from each column signal processing circuit 120 through the horizontal signal line 144. For example, the output circuit 128 can perform a buffering, black level adjustment, column variation correction, various digital signal processing, and other signal processing procedures. An input and output terminal 148 exchanges signals between the image sensor 100 and external components or systems.

Accordingly, a color sensing image sensor 100 in accordance with at least some embodiments of the present disclosure can be configured as a CMOS image sensor of a column A/D type in which column signal processing is performed.

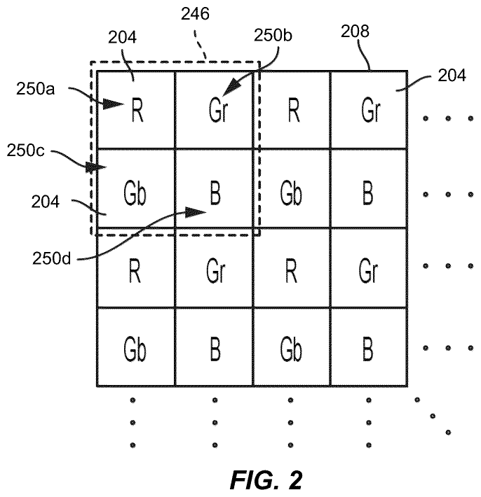

With reference now to FIG. 2, portions of a pixel array 208 of an exemplary color sensing image sensor in accordance with the prior art are depicted. FIG. 2 shows a portion of the pixel array 208 in a plan view and illustrates how individual pixels 204 are disposed in 2×2 sets 246 of four pixels 204. In this particular example, each 2×2 set 246 of four pixels 204 is configured as a so-called Bayer array, in which a first one of the pixels 204 is associated with a red color filter 250a, a second one of the pixels 204 is associated with a green color filter 250b, a third one of the pixels 204 is associated with another green color filter 250c, and fourth one of the pixels 204 is associated with the blue color filter 250d. Each of the four pixels 204 may be covered by the same or a different spectral filter as described herein.

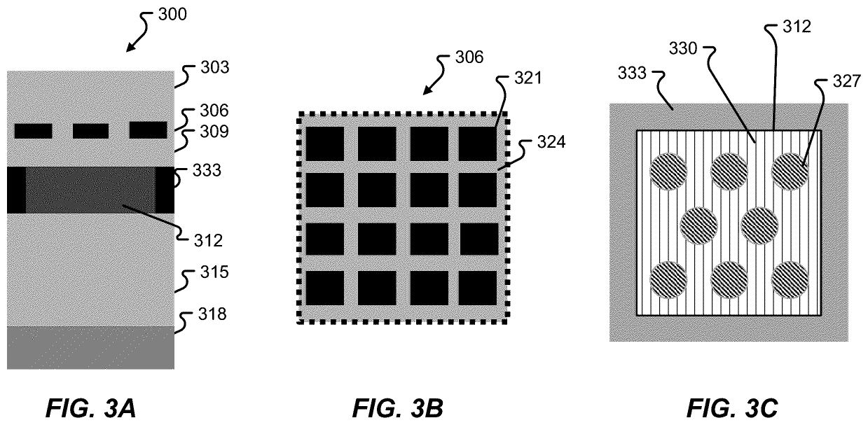

As illustrated in FIG. 3A, a mode resonant filter 300 for hyperspectral sensing may comprise a stack layout including a number of features such as a silicon substrate 318, a buried layer 315 of, for example, silicon dioxide (SiO₂), a metamaterial layer 312, a coupling layer 309, a metal grating layer 306, and an SiO₂ covering 303.

It should be appreciated that in some embodiments, the filter 300 may include a greater number or lesser number of the features described herein. For example, in some embodiments, a color filter and/or micro lens may be mounted on the SiO₂ covering 303 or the metal grating layer 306. Furthermore, it should be appreciated that in some embodiments the features of the filter 300 may be rearranged. For example, a filter 300 may comprise a grating layer 306 between the metamaterial 312 and the substrate 318.

The filter 300 may comprise a metal grating layer 306 which may be constructed as illustrated in FIG. 3B. The metal grating layer 306 may comprise a plurality of metallic portions 321 such as aluminum (Al) squares surrounded by a material 324 such as SiO₂ or another substance. In some embodiments, the metallic portions 321 may comprise Al grating rectangular prisms of a particular width, such as 230 nm. The Al grating rectangular prisms may be of a same length or thickness as the metal grating layer 306 itself. The Al grating rectangular prisms may be separated by a distance of, for example, 120 nm.

FIG. 3B shows a top down view of a metal grating layer 306. As can be appreciated, the grating design may be in a square pattern. However, it should be appreciated that in some embodiments the grating may be in other designs. A square pattern, as illustrated in FIG. 3B combines linear polarization components in different directions, such that light, whether linearly polarized at an angle or unpolarized, will exhibit the same transmitted intensity upon reaching the sensor beneath the filter. Such a design allows for a response to incoming light to be insensitive to any polarization of the incoming light.

In some embodiments, the metal grating comprises an Al grating, though it should be appreciated that in some embodiments other metals may be used. The metal grating may be, for example, of a particular thickness, such as 15 nm, less than 30 nm, or another thickness depending on demands of a particular application such as a desired wavelength or range of wavelengths to be transmitted by the particular filter.

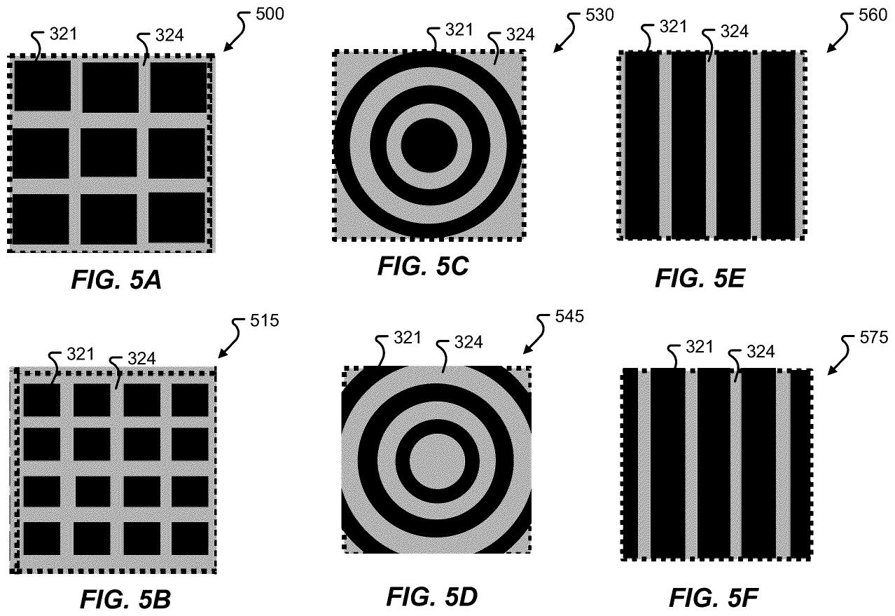

As illustrated in FIGS. 5A and 5B, a grating layer 500, 515 may in some embodiments comprise a grid of Al grating square metallic portions 321 surrounded by a material 324 of, for example, SiO₂. The Al grating squares may be, for example, between 200 nm and 250 nm wide and may be separated by between 100 nm and 150 nm of SiO₂ material 324, though it should be appreciated other sizes and thicknesses may be appropriate in certain situations. Also, the grid may be a three-by-three grid of metallic portions 321 or any number by any number of metallic portions 321. While grids of grating squares as described herein are illustrated as being grids of equal numbers of squares in either direction, it should be appreciated grids of other shapes and sizes could be implemented.

As illustrated in FIGS. 5C and 5D, in some embodiments, a grating layer 530, 545 may be of other shapes and sizes. For example, as illustrated in FIGS. 5C and 5D, the Al grating may comprise metallic portions 321 of concentric circles of Al or another metal separated by a material 324 of circles of SiO₂ or another material. As should be appreciated, the circular shape of metallic portions 321 or the material 324 may in some embodiments be cut off at a square edge in order to fit within a particular pixel size to fit into an array.

As illustrated in FIGS. 5E and 5F, a grating layer 560, 575 may in some embodiments comprise metallic portions 321 of parallel lines of Al separated by material 324 of parallel lines of SiO₂ as opposed to a grid. The parallel lines of grating layers 560, 575 may be suitable for particular embodiments based on polarization. With proper polarization, the filters may achieve ideal performance, while light of off-polarization may result in a decrease of performance.

Any of the grating layers as described herein may be used to tune a filter to achieve a desired response to light. By adjusting the materials and patterns of grating layers, the wavelengths of light passed through the grating layer. When tuned in conjunction with a layer of metamaterial as described herein, light of a particular wavelength or range of wavelengths may be transmitted by a filter while light outside of the particular wavelength or range of wavelengths may be effectively blocked.

Grating layers as described herein may comprise either metal or SiO₂ or a combination thereof at the edge. Metal at edges may help prevent crosstalk, but also may cause unrealizable manufacturing conditions. As such, it may be beneficial to implement a grating layer in which metal portions are surrounded by a material such as SiO₂.

While certain patterns of metal portions in grating layers are illustrated and described herein, it should be appreciated other patterns may be used depending on application requirements in other embodiments. Also, filters with grating layers comprising different patterns may be used alongside each other on a single substrate such that different pixels may receive light filtered through different grating layers.

In some embodiments, a filter 300 may comprise a coupling layer 309 of a material such as SiO₂ which may separate a grating layer 306 from a layer of metamaterial 312. The coupling layer may in some embodiments be between 20 nm and 40 nm thick. For example, a 30 nm thick coupling layer may be used.

In some embodiments, a filter 300 may comprise a layer of metamaterial 312 which may be surrounded, at least in some embodiments, by an isolation region 333.

A metamaterial 312 of the filter 300 may comprise portions of a first material, such as Si₃N₄, dispersed within a second material, such as TiO₂, in one or more patterns as described herein. The metamaterial may be, for example, 200 nm thick, or another thickness, such as between 150 and 250 nm.

FIG. 3C shows a top down view of a resonant layer of metamaterial 312, in accordance with at least one embodiment of the metamaterial layout. The contrasting colors show physical placement of two types of materials 327, 330. By altering the number of different materials, the refractive index of the resonant layer can be changed.

The metamaterial 312 may be as illustrated in FIG. 3C. The metamaterial 312 may comprise a plurality of cylindrical columns of a first material 327, for example of TiO₂, surrounded by a second material 330, such as Si₃N₄.

In some embodiments, the cylindrical columns of TiO₂ are between 250 nm and 300 nm in diameter and between 150 nm and 250 nm in depth and each cylindrical column of TiO₂ is separated from another cylindrical column of TiO₂ by between 100 nm and 150 nm. In at least one embodiment, the cylindrical columns of the first material 327 are of a 280 nm diameter and separated by a gap of 120 nm.

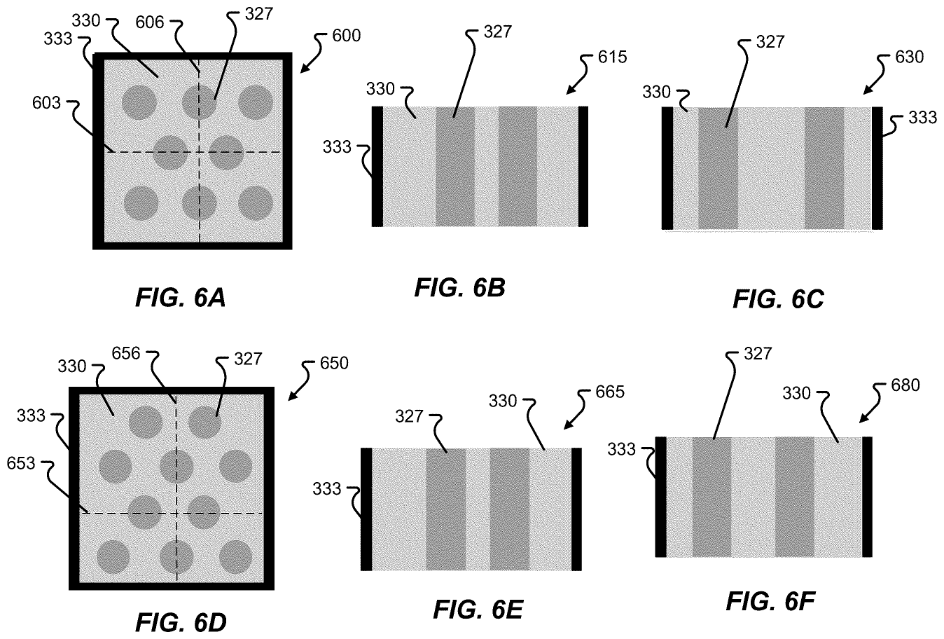

In some embodiments, a filter may comprise a metamaterial 600 which may be as illustrated in FIGS. 6A-6C. A metamaterial as described herein may comprise one or more materials such as TiO₂, Si₃N₄, and/or other materials. The makeup of the metamaterial may be selected based on a desired wavelength or range of wavelengths to be transmitted through a filter comprising the metamaterial. By tuning both a grating layer and a metamaterial of a filter, a particular wavelength or range of wavelengths of light may be selected to be transmitted through the filter.

In some embodiments, the metamaterial 600 comprises a first material 327 disposed in cylindrical columns surrounded by a second material 330. The metamaterial 600 illustrated in FIG. 6A includes approximately 30% of the first material 327 and approximately 70% of the second material 330. It should be appreciated that metamaterials of other embodiments may contain other amounts of first and second materials and may contain only a single material or more than two materials.

By altering the amounts of materials in a metamaterial of a filter, the effective refractive index or the resonant frequency of the metamaterial may be adjusted. The ratio between first material 327 and second material 330, and/or any other materials, may be adjusted based on a desired resonance. For example, a ratio of a first material 327 and a second material 330 may be selected such that the metamaterial does not interact with a particular wavelength or wavelengths of interest for the particular application for which the metamaterial is to be used. The ratio may be any number from 100% of the first material 327 and 0% of the second material 330 to 0% of the first material 327 and 100% of the second material 330. For example, in at least one embodiment, the metamaterial may comprise 30% of the first material 327 and 70% of the second material 330.

The dimensions of the metamaterial layer may be set to control the refractive index and/or resonant frequency. It may be necessary to set dimensions of the metamaterial layer to be a distance different from the desired wavelength or range of wavelengths so as to avoid interactions. It should be appreciated a variety of different dimensions may be used in filters depending on the wavelengths or range of wavelengths to be transmitted.

FIGS. 6B and 6C illustrate cross-section view of the metamaterial 600 of FIG. 6A. A cross-section 615 of the metamaterial 600 along an axis 603 is illustrated in FIG. 6B and a cross-section 630 along an axis 606 is illustrated in FIG. 6C.

As should be appreciated, the cylindrical columns of the first material 327 may extend the full depth of the layer of metamaterial 600 and may be surrounded by an isolation layer 333 as described below. The isolation layer 333 may be, for example, of a thickness of 50-100 nm. In some embodiments, a minimal thickness of isolation material may be set based on an amount necessary to prevent crosstalk between devices.

The cylindrical columns of the first material 327 may have a diameter of, for example, 240 nm or 280 nm or another distance. The cylindrical columns of the first material 327 may be separated from other columns of the first material 327 in a same row by, for example, 120 nm or another distance, and from other columns of the first material 327 in a different row by, for example, 380-420 nm.

Another example metamaterial 650 which may be comprised by a filter in some embodiments is illustrated in FIGS. 6D-6F. A cross-section 665 of the metamaterial 650 along an axis 653 is illustrated in FIG. 6E and a cross-section 680 of the metamaterial 650 along an axis 656 is illustrated in FIG. 6F. While each of the illustrations of metamaterial show a first material disposed in cylindrical columns or prisms, it should be appreciated that in some embodiments other designs may be used.

In some embodiments, the metamaterial 312 may be surrounded by an isolation region 333. The isolation region 333 may be of a same thickness as the metamaterial 312 or may be a greater or lesser thickness. The isolation layer may be of a particular width, such as 100 nm or another width. Isolation may be used to ensure light passing through a grating of a first filter does not crossover into any other filter. It should be appreciated, though, that a filter may be designed without any such isolation region.

In some embodiments, the isolation region may comprise aluminum (Al). Since the operation of a conventional device including a filter depends on resonance features, conventional filter designs have used a large format that provides resonant build up across a large region. Using an Al isolation region as described herein, resonance features from outside the design area can be blocked. In this way, a single pixel may be isolated. Because a filter as described herein can be used to isolate a pixel, each pixel may be enabled to be operated alone, independent of other neighboring pixels. Using an Al isolation region as described herein may also help to control crosstalk between pixels, as it blocks a large amount of light that would be worrisome for crosstalk concerns.

As illustrated in FIGS. 3A and 3C, and as discussed above, an isolation region 333 may surround a metamaterial layer 312. The isolation region 333 may be a same depth or thickness as the metamaterial layer 312 as illustrated in FIG. 3A. However, it should be appreciated that in some embodiments other thicknesses may be used.

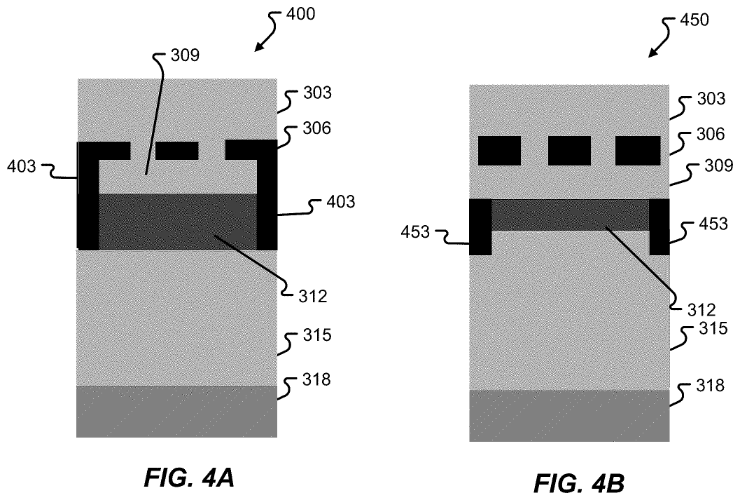

For example, as illustrated in FIG. 4A, in some embodiments, a filter 400 may comprise an isolation region 403 which extends from a bottom surface of a metamaterial layer 312 up through a coupling layer 309 and to a grating layer 306. In some embodiments, a single piece of aluminum may act as both an isolation region and at least a portion of a grating layer by extending up to the grating layer.

Depending on the desired application, extending an isolation region 403 as illustrated in FIG. 4A may be desirable due to an increase in isolation characteristics. However, in some applications a minimal isolation region may be desirable due to a decrease in light transmission. For example, if the base transmission of received light is relatively high, a decrease in light transmission may not greatly affect the performance of the sensor. In such a situation, a greater amount of isolation may be desirable. In other situations, such as low-light situations, a lesser amount of isolation may be desired.

As illustrated in FIG. 4B, in some embodiments, a filter 450 may comprise an isolation region 453 which may begin below a bottom surface of a metamaterial layer 312 and extend upward to a top surface of the metamaterial layer 312. While the embodiments illustrated in FIGS. 3A, 3C, 4A, and 4B show three arrangements of isolation regions, it should be appreciated that in other embodiments other layouts or a combination thereof may be used.

Isolation regions as described herein may be used to minimize crosstalk and to allow multiple devices to be next to one another without affecting the thickness of a filter. As such, an array of devices including such filters may be deployed and each filter may have the same or a different arrangement of isolation. For example, the filter 400 may be placed directly next to the filter 450. In this way, a grid of filters may be implemented on a single sensor.

The isolation may in some embodiments comprise, for example, a region of metal such as Al or another metal, or may comprise a dielectric, or air isolation. Avoiding metal by using dielectric or air may result in increased transmission and more crosstalk, as light may not be as well bound to the pixel. However, if crosstalk is not a major concern, the use of dielectric or air may be appropriate in certain applications based on factors such as manufacturing costs and complexities or other reasons.

In some embodiments, a filter 300 may comprise an SiO₂ covering over the metal grating. The SiO₂ covering may enable the filter 300 to have a level top surface onto which a micro lens or color filter may be mounted on a light receiving side of the filter 300.

In some scenarios, additional spectral isolation may be desired. For example, multiple resonances across different wavelengths may occur. In such scenarios, color filters may act as a further spectral isolation unit for the hyperspectral filters. For example, color filters may be used to select one transmission peak to pass through a particular one or more filters to reach one or more respective pixels. A single color filter may cover only one or multiple hyperspectral filters.

The filter 300 may comprise a buried layer 315 of a material such as SiO₂ between the metamaterial 312 and the substrate 318. In some embodiments, the buried layer 315 is 325 nm thick, though it should be appreciated in some embodiments other thicknesses may be used.

The buried SiO₂ region is a layer which may be used to compensate for different changing thicknesses of other layers such as a grating layer and/or a metamaterial layer. For example, a plurality of filters, each acting as a different device, may be deployed on a single sensor. It may be desirable for each filter, or device, to have a same final thickness so that a plurality of the filters can be used together in a snapshot hyperspectral filter. By adjusting the thickness of the buried SiO₂ region to account for differences in thicknesses of grating layers and/or metamaterial layers in different filters, the thickness of each filter may be the same. This constraint enables nanoscale patterning to occur throughout the full device or plurality of filters.

The buried SiO₂ region may also help to regulate the full-width half-maximum (FWHM) of the final transmission of light through the filter based on the desired wavelength or range of wavelengths to be passed through the filter.

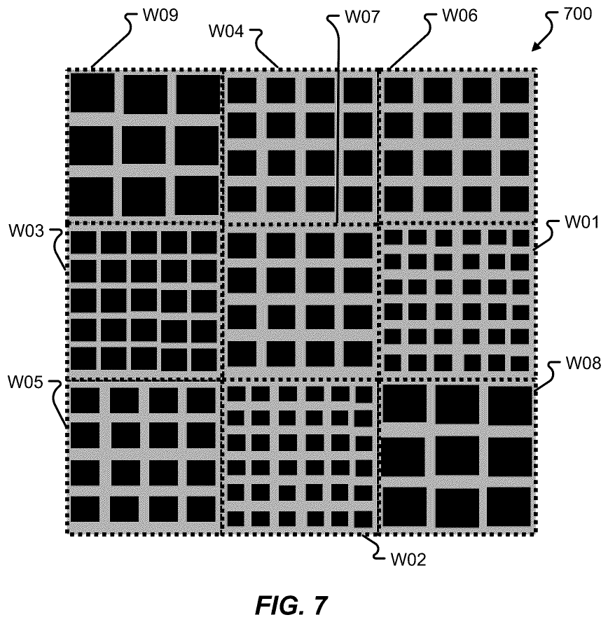

In some embodiments, filters may be used as a grid 700 of devices W01-W09 as illustrated in FIG. 7. In the embodiment illustrated in FIG. 7, a grid 700 of devices W01-W09 comprise a variety of grating layers. In the top-down view of the grid 700, only the grating layer can be seen, but it should be appreciated that each device W01-W09 may comprise a stack layout such as illustrated in any one of FIGS. 3A, 4A, and 4B. The devices W01-W09 may each comprise a metamaterial such as illustrated in FIGS. 3C and 6A-6F. As illustrated in FIG. 7, devices W09 and W08 each comprise a three-by-three grating layout, devices W04, W05, W06, and W07 each comprise a four-by-four grating layout, device W03 comprises a five-by-five grating layout, and devices W01 and W02 each comprise a six-by-six grating layout. As described throughout, the square grids of grating layers are provided as example, yet it should be appreciated in some embodiments other layouts, such as those illustrated in FIGS. 5C-5F may be used.

Each device of a grid of devices may include a different grating layer design and/or a different metamaterial design. The grating layer and metamaterial of each device may be selected in order to enable the device to pass light of a particular wavelength or range of wavelengths.

Each device may be positioned over one or more pixels on a substrate. Because an isolation region is built into the design of the filters, as illustrated in FIGS. 3A, 4A, and 4B, the filters may be placed next to other filters on the same substrate without incurring crosstalk issues.

As described herein, each device W01-W09 comprises a variety of variable features. For example, the layout of the grating and the resonant materials of the metamaterial may be adjusted to enable each filter of each device to transmit light of a particular wavelength or range of wavelengths. Because each filter may transmit light of a different wavelength or range of wavelengths, a grid of devices such as illustrated in FIG. 7 may be deployed on a single substrate. Despite each filter being designed to transmit a different wavelength of light, each filter may be of a same thickness such that a single color filter or micro lens may cover one or more of the filters. As described below, each of W01-W09 may comprise filters with a variety of grids of Al squares, each designed to provide a desired resonant thickness. Each may be one of a 3×3, 4×4, 5×5, 6×6, or other layout of Al squares. An overall width of the grids may be equal, thus squares of grids with fewer squares, e.g., a 3×3 grid may be wider than squares of grids with a greater number of squares, e.g., a 6×6 grid.

A first filter, W01, of the grid 700 may be designed to pass light of a wavelength of 458 nm. The grating of the W01 filter may comprise a 6×6 grid of Al squares, each square with a width of, for example, 130 nm, to provide a desired resonant thickness. The metamaterial may comprise, for example, 90 nm of Si3N4. The W01 filter may enable light of wavelength 458 nm to pass through at a peak transmission level of 28%.

A second filter, W02, of the grid 700 may be designed to pass light of a wavelength of 506 nm. The grating of the W02 filter may comprise a 6×6 grid of Al squares, each square with a resonant thickness width of, for example, 130 nm, to provide a desired resonant thickness. The metamaterial may comprise, for example, 90 nm of TiO₂. The W02 filter may enable light of wavelength 506 nm to pass through at a peak transmission level of 28%.

A third filter, W03, of the grid 700 may be designed to pass light of a wavelength of 534-540 nm. The grating of the W03 filter may comprise a 5×5 grid of Al squares, each square with a resonant thickness width of, for example, 180 nm, to provide a desired resonant thickness. The metamaterial may be, for example, 90 nm thick and comprise 75% TiO₂ and 25% Si3N4. The W03 filter may enable light of wavelength 534-540 nm to pass through at a peak transmission level of 33%.

A fourth filter, W04, of the grid 700 may be designed to pass light of a wavelength of 639 nm. The grating of the W04 filter may comprise a 4×4 grid of Al squares, each square with a resonant thickness width of, for example, 255 nm, to provide a desired resonant thickness. The metamaterial may comprise, for example, 90 nm of TiO₂. The W04 filter may enable light of wavelength 639 nm to pass through at a peak transmission level of 35%.

A fifth filter, W05, of the grid 700 may be designed to pass light of a wavelength of 691 nm. The grating of the W05 filter may comprise a 4×4 grid of Al squares, each square with a resonant thickness width of, for example, 255 nm, to provide a desired resonant thickness. The metamaterial may be, for example, 230 nm thick and comprising 75% Si₃N₄ and 25% TiO₂. The W05 filter may enable light of wavelength 691 nm to pass through at a peak transmission level of 27%.

A sixth filter, W06, of the grid 700 may be designed to pass light of a wavelength of 735 nm. The grating of the W06 filter may comprise a 4×4 grid of Al squares, each square with a resonant thickness width of, for example, 255 nm, to provide a desired resonant thickness. The metamaterial may be, for example, 230 nm thick and comprising 75% TiO₂ and 25% Si₃N₄. The W06 filter may enable light of wavelength 735 nm to pass through at a peak transmission level of 31-35%.

A seventh filter, W07, of the grid 700 may be designed to pass light of a wavelength of 771 nm. The grating of the W07 filter may comprise a 4×4 grid of Al squares, each square with a resonant thickness width of, for example, 255 nm, to provide a desired resonant thickness. The metamaterial may be, for example, 230 nm thick and comprise TiO₂. The W07 filter may enable light of wavelength 771 nm to pass through at a peak transmission level of 35%.

An eighth filter, W08, of the grid 700 may be designed to pass light of a wavelength of 875 nm. The grating of the W08 filter may comprise a 3×3 grid of Al squares, each square with a resonant thickness width of, for example, 400 nm, to provide a desired resonant thickness. The metamaterial may be, for example, 230 nm thick and comprise Si₃N₄. The W08 filter may enable light of wavelength 875 nm to pass through at a peak transmission level of 23%.

A ninth filter, W09, of the grid 700 may be designed to pass light of a wavelength of 925 nm. The grating of the W09 filter may comprise a 3×3 grid of Al squares, each square with a resonant thickness width of, for example, 400 nm, to provide a desired resonant thickness. The metamaterial may be, for example, 230 nm thick and comprising 75% TiO₂ and 25% Si₃N₄. The W09 filter may enable light of wavelength 925 nm to pass through at a peak transmission level of 36%.

As should be appreciated, the peak wavelength passed by a filter may be controlled through modification of one or more of the grating and the metamaterial. As should also be appreciated, the various examples of wavelengths, thicknesses, and widths described herein are provided for the purpose of illustration only and should not be considered as limiting in any way. Other amounts are contemplated and may be possible depending on particular demands of particular embodiments.

As described above in relation to FIG. 1, an image sensor 100 includes a plurality of pixels 104 disposed in an array 108 and formed in an imaging or semiconductor substrate 112. Using an array of filters as described herein, each pixel 104 may be enabled to receive light of a different wavelength or range of wavelengths. In addition, one or more color filters and/or micro lenses may cover one or more of the pixels 104. Accordingly, a color sensing image sensor 100 in accordance with at least some embodiments of the present disclosure can be configured as a CMOS image sensor of a column A/D type in which column signal processing is performed.

As described above in relation to FIG. 2, portions of a pixel array 208 of an exemplary color sensing image sensor in accordance with the prior art are depicted. FIG. 2 shows a portion of the pixel array 208 in a plan view and illustrates how individual pixels 204 are disposed in 2×2 sets 246 of four pixels 204. In this particular example, each 2×2 set 246 of four pixels 204 is configured as a so-called Bayer array, in which a first one of the pixels 204 is associated with a red color filter 250a, a second one of the pixels 204 is associated with a green color filter 250b, a third one of the pixels 204 is associated with another green color filter 250c, and fourth one of the pixels 204 is associated with the blue color filter 250d. It should be appreciated each of the pixels 204 may be further associated with a respective hyperspectral filter as described herein.

Embodiments of the present disclosure include a method of manufacturing a mode resonant filter for hyperspectral sensing, the method comprising dispersing a metamaterial layer on a first layer of SiO₂. The metamaterial may be dispersed between portions of or in a hole in an isolation region. A second layer of SiO₂ may be dispersed on the metamaterial layer, and a metal grating layer may be dispersed on the second layer of SiO₂. A top layer of SiO₂ may be formed on the metal grating layer, and one or more of a color filter and a micro lens may be placed on the top layer of SiO₂.

The foregoing has been presented for purposes of illustration and description. Further, the description is not intended to limit the disclosed systems and methods to the forms disclosed herein. Consequently, variations and modifications commensurate with the above teachings, within the skill or knowledge of the relevant art, are within the scope of the present disclosure. The embodiments described hereinabove are further intended to explain the best mode presently known of practicing the disclosed systems and methods, and to enable others skilled in the art to utilize the disclosed systems and methods in such or in other embodiments and with various modifications required by the particular application or use. It is intended that the appended claims be construed to include alternative embodiments to the extent permitted by the prior art.

What is claimed is:

1. A mode resonant filter for hyperspectral sensing, the filter comprising:
a metal grating;
a coupling layer; and
a metamaterial.

2. The filter of claim 1, wherein the metal grating comprises an aluminum (Al) grating.

3. The filter of claim 2, wherein the Al grating is less than 30 nm thick.

4. The filter of claim 2, wherein the Al grating comprises a grid of Al grating squares surrounded by SiO₂.

5. The filter of claim 4, wherein the Al grating squares are between 200 nm and 250 nm wide.

6. The filter of claim 4, wherein each of the Al grating squares are separated by between 100 nm and 150 nm.

7. The filter of claim 2, wherein the Al grating comprises parallel lines of Al separated by parallel lines of SiO₂.

8. The filter of claim 2, wherein the Al grating comprises concentric circles of Al separated by circles of SiO₂.

9. The filter of claim 1, wherein the coupling layer is between 20 nm and 40 nm thick.

10. The filter of claim 1, wherein the metamaterial comprises Si₃N₄ and TiO₂.

11. The filter of claim 10, wherein the metamaterial comprises a plurality of cylindrical columns of TiO₂ surrounded by Si₃N₄.

12. The filter of claim 11, wherein the cylindrical columns of TiO₂ are between 250 nm and 300 nm in diameter and between 150 nm and 250 nm in depth.

13. The filter of claim 11, wherein each cylindrical column of TiO₂ is separated from another cylindrical column of TiO₂ by between 100 nm and 150 nm.

14. The filter of claim 10, wherein the metamaterial is surrounded by an isolation region.

15. The filter of claim 14, wherein the isolation region comprises one or more of an Al, a dielectric, and air.

16. The filter of claim 1, further comprising a SiO₂ covering over the metal grating.

17. A sensor comprising a mode resonant filter for hyperspectral sensing, the filter comprising:
a metal grating;
a coupling layer; and
a metamaterial.

18. The sensor of claim 17, further comprising a buried SiO₂ layer between the metamaterial and a substrate.

19. The sensor of claim 17, further comprising one or more of a color filter and a micro lens on a light receiving side of the metal grating.

20. An imaging device, comprising:
a pixel array unit, wherein the pixel array unit comprises:
a plurality of pixels; and
a plurality of mode resonant filters, wherein each filter includes:
a metamaterial on a first layer of SiO₂;
a second layer of SiO₂ on the metamaterial; and
a metal grating on the second layer of SiO₂.
